(19) United States
(12) Patent Application Publication
(10) Pub. No.: US 2024/0006211 A1
(43) Pub. Date: Jan. 4, 2024

(54) PROTECTIVE PACKAGE ASSEMBLY

(71) Applicants: GUDENG PRECISION INDUSTRIAL CO., LTD., NEW TAIPEI CITY (TW); TAIWAN SEMICONDUCTOR MANUFACTURING COMPANY, LTD., Hsinchu (TW)

(72) Inventors: Ming-Chien CHIU, NEW TAIPEI CITY (TW); En-Nien SHEN, NEW TAIPEI CITY (TW); Chia-Ho CHUANG, NEW TAIPEI CITY (TW); Kuo-Hua LEE, NEW TAIPEI CITY (TW); Jyun-Ming LYU, NEW TAIPEI CITY (TW); Tzu Ang CHIANG, I-lan (TW); Yi-Feng HUANG, Kaohsiung City (TW); Tsung-Yi LIN, Tainan City (TW)

(73) Assignees: GUDENG PRECISION INDUSTRIAL CO., LTD., NEW TAIPEI CITY (TW); TAIWAN SEMICONDUCTOR MANUFACTURING COMPANY, LTD., Hsinchu (TW)

(21) Appl. No.: 18/329,271

(22) Filed: Jun. 5, 2023

Related U.S. Application Data
(60) Provisional application No. 63/357,011, filed on Jun. 30, 2022.

(30) Foreign Application Priority Data
Apr. 25, 2023 (TW) 112115403

(51) Int. Cl. H01L 21/673; B65D 81/02

(52) U.S. Cl. CPC H01L 21/67369; B65D 81/022

(57) ABSTRACT

A protective package assembly includes middle, upper, and lower packages. The middle package includes side buffer boards. The side buffer boards are connected in a ring shape to form an accommodating space communicated with upper and lower openings. The upper package includes an upper buffer board and upper buffer members. The upper buffer board is configured to cover the upper opening. The upper buffer members are distributed at intervals and protrude from a surface of the upper buffer board. The upper buffer members are disposed toward the interior of the accommodating space. The lower package includes a lower buffer board and lower buffer members. The lower buffer board is configured to cover the lower opening. The lower buffer members are distributed at intervals and protrude from a surface of the lower buffer board. The lower buffer members are disposed toward the interior of the accommodating space.

### CROSS-REFERENCE TO RELATED APPLICATION

This application claims priority to U.S. Provisional Application Ser. No. 63/357,011 filed Jun. 30, 2022, and Taiwan Application Serial Number 112115403, filed Apr. 25, 2023, the disclosures of which are incorporated herein by reference in their entireties.

### BACKGROUND

### Technical Field

The present disclosure relates to a protective package assembly.

### Description of Related Art

Currently, the semiconductor industry uses substrate containers to hold substrates. The substrates can be semiconductor devices such as printed circuit boards (PCBs) or wafers. During the transportation of a substrate container, it is easy to cause the substrates to break due to excessive vibration, or cause the devices in the substrate container to loosen from each other. Alternatively, the devices in the substrate container may generate dusts due to friction with each other, thereby seriously affecting the cleanliness of the substrate container. In addition, the substrate container may also cause dust problems during the transmission and positioning operation in conjunction with the equipment interface.

In order to allow the substrate container to be cushioned and protected during the process of transporting the substrate container, the existing method is to use a packaging material with a cushioning function to cover the substrate container. The structural design of the existing packaging material often adopts the form of covering the edges and corners of the substrate container and attaching entire surfaces of the substrate container, so that when the substrate container is subjected to vibration, the cushioning function of the packaging material can produce the effect of covering and protecting. However, the aforementioned method is only effective for small vibrations, and cannot provide protection and buffering for large vibrations, or when the substrate container is dropped from a height of more than ten centimeters.

Accordingly, how to provide a protective package assembly to solve the aforementioned problems becomes an important issue to be solved by those in the industry.

### SUMMARY

An aspect of the disclosure is to provide a protective package assembly that can efficiently solve the aforementioned problems.

According to an embodiment of the disclosure, a protective package assembly includes a middle package, an upper package, and a lower package. The middle package includes a plurality of side buffer boards. The side buffer boards are connected in a ring shape to form an accommodating space communicated with an upper opening and a lower opening. The upper package includes an upper buffer board and a plurality of upper buffer members. The upper buffer board is configured to cover the upper opening. The upper buffer members are distributed at intervals and protrude from a surface of the upper buffer board. The upper buffer members are disposed toward an interior of the accommodating space. The lower package includes a lower buffer board and a plurality of lower buffer members. The lower buffer board is configured to cover the lower opening. The lower buffer members are distributed at intervals and protrude from a surface of the lower buffer board. The lower buffer members are disposed toward the interior of the accommodating space.

In an embodiment of the disclosure, the accommodating space of the middle package has an annular inner surface. The upper buffer members includes a first upper buffer member and a second upper buffer member. A height of the first upper buffer member is greater than a height of the second upper buffer member. A shortest distance from the second upper buffer member to the annular inner surface is greater than a shortest distance from the first upper buffer member to the annular inner surface.

In an embodiment of the disclosure, the upper buffer members includes a plurality of first upper buffer members and a second upper buffer member. A height of the first upper buffer members is greater than a height of the second upper buffer member. The first upper buffer members are arranged around a periphery of the second upper buffer member.

In an embodiment of the disclosure, top surfaces of the lower buffer members are coplanar.

In an embodiment of the disclosure, the upper buffer members are a combination of different areas and arranged at intervals.

In an embodiment of the disclosure, the lower buffer members are a combination of an identical area.

In an embodiment of the disclosure, when the protective package assembly accommodates an object weighing less than ten kilograms and is subjected to a drop test from a height greater than ten centimeters, a total cushioning force of the protective package assembly is greater than cushioning forces of a corner, an edge, and a surface of the protective package assembly, and the cushioning forces of the corner and the edge is greater than the cushioning force of the surface.

In an embodiment of the disclosure, the protective package assembly is a combined structure of the middle package, the upper package, and the lower package.

In an embodiment of the disclosure, a material of the middle package, the upper package, and the lower package is foamed polyethylene.

In an embodiment of the disclosure, at least one of the side buffer boards has a thickness smaller than a thickness of other side buffer boards.

Accordingly, in the protective package assembly of the present disclosure, by virtue of the combined structure of the middle package, the upper package, and the lower package, the outer periphery of the substrate container can be completely covered. Specifically, a plurality of upper buffer members are disposed on the upper buffer board of the upper package, and a plurality of lower buffer members are disposed on the lower buffer board of the lower package. The heights of these upper buffer members and the lower buffer members can be correspondingly adjusted according to the top structure and the bottom structure of the substrate container, so that the upper package and the lower package can closely fit the irregular undulating contours of the top and bottom of the substrate container. Moreover, the cushioning forces of the upper package and the lower package disclosed in the present disclosure are greater than those of a traditional structural design of integrally attached to the substrate container, so the effect of cushioning and shock resistance can be more effectively achieved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is an exploded perspective view of a protective package assembly according to an embodiment of the disclosure;

FIG. 1B is an exploded assembled view of the protective packaging assembly in FIG. 1A;

FIG. 2 is an exploded perspective view of the protective package assembly and a substrate container according to an embodiment of the disclosure;

FIG. 3 is a side view of the protective package assembly in FIG. 2 packaging the substrate container;

FIG. 4 is a front view of the protective package assembly in FIG. 2 packaging the substrate container;

FIG. 5 is a cross-sectional view of the structure in FIG. 3 cut along line 5-5;

FIG. 6 is a cross-sectional view of the structure in FIG. 4 cut along line 6-6;

FIG. 7 is a cross-sectional view of the structure in FIG. 3 cut along line 7-7; and

FIG. 8 is a cross-sectional view of the structure in FIG. 3 cut along line 8-8.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

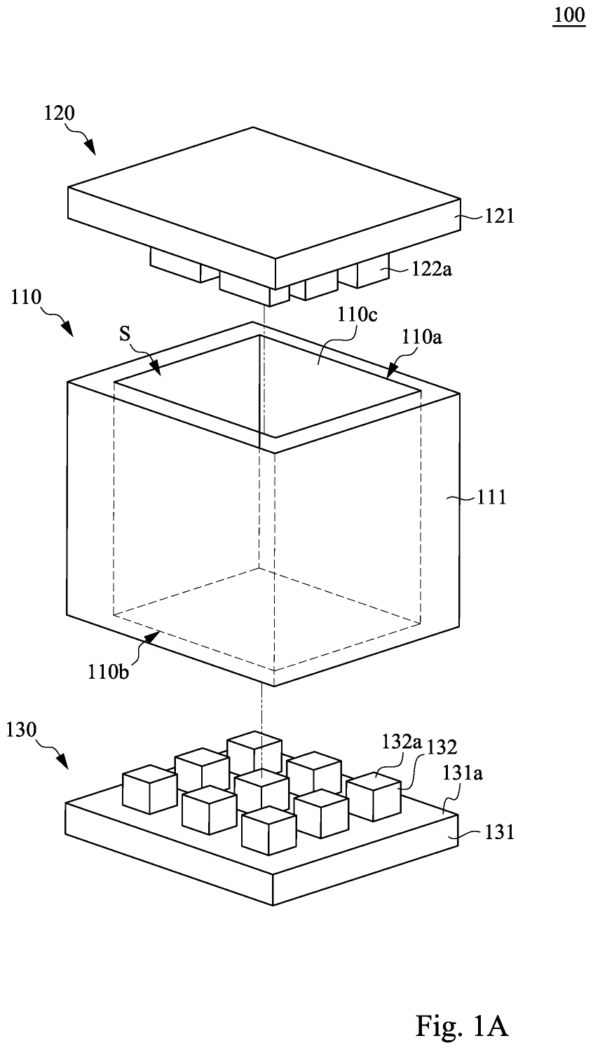

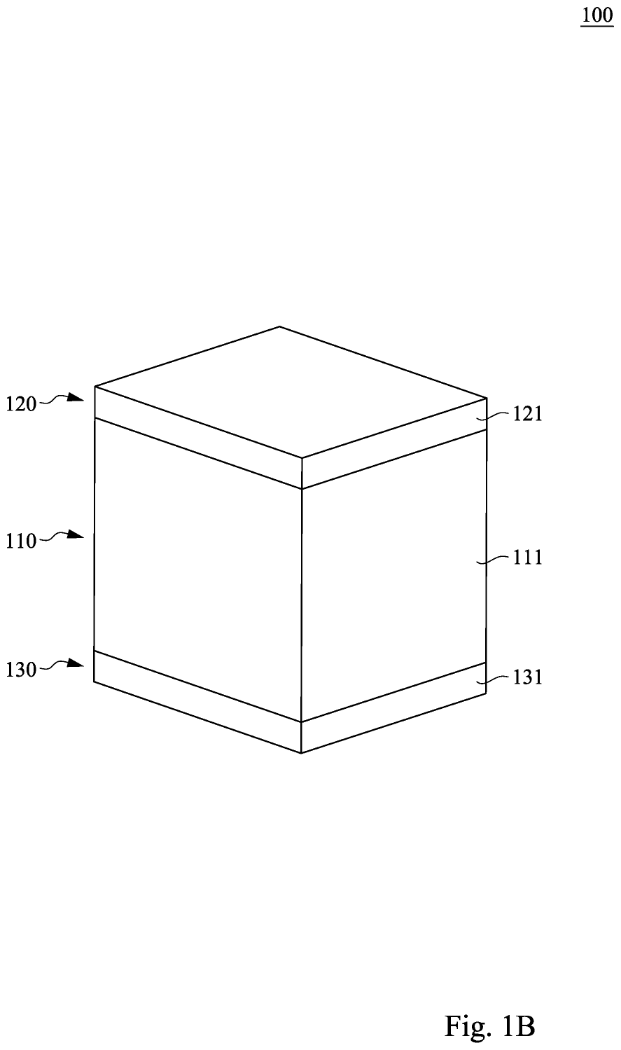

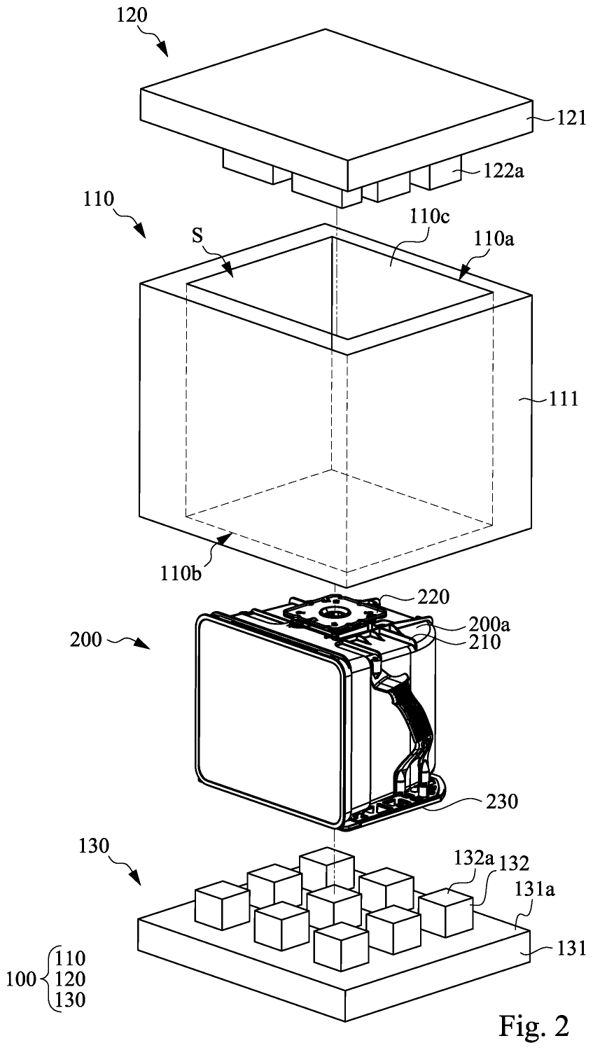

Reference is made to FIGS. 1A, 1B, and 2. FIG. 1A is an exploded perspective view of a protective package assembly 100 according to an embodiment of the disclosure. FIG. 1B is an exploded assembled view of the protective packaging assembly 100 in FIG. 1A. FIG. 2 is an exploded perspective view of the protective package assembly 100 and a substrate container 200 according to an embodiment of the disclosure. In order to clearly illustrate the specific structure, the middle package 110 is presented in a perspective manner in FIG. 1A and FIG. 2. As shown in FIGS. 1A to 2, in the present embodiment, the protective package assembly 100 includes a middle package 110, an upper package 120, and a lower package 130. The middle package 110 includes a plurality of side buffer boards 111. The side buffer boards 111 are connected in a ring shape to form an accommodating space S communicated with an upper opening 110a and a lower opening 110b. Specifically, the accommodating space S of the middle package 110 has an annular inner surface 110c. The upper package 120 includes an upper buffer board 121. The upper buffer board 121 is configured to cover the upper opening 110a of the middle package 110. The lower package 130 includes a lower buffer board 131. The lower buffer board 131 is configured to cover the lower opening 110b of the middle package 110. In this way, the upper package 120 and the lower package 130 can seal the accommodating space S of the middle package 110 to achieve the purpose of completely packaging the substrate container 200 inside the protective package assembly 100. In other words, the protective package assembly 100 is a combined structure of the middle package 110, the upper package 120, and the lower package 130.

In practical applications, the substrate container 200 may be a front opening unified pod (FOUP), a standard mechanical interface (SMIF), or a front opening shipping box (FOSB). As long as the protective package assembly 100 can be used in the present disclosure, it should be included in the scope of the present disclosure, and the present disclosure does not limit the type of the substrate container 200.

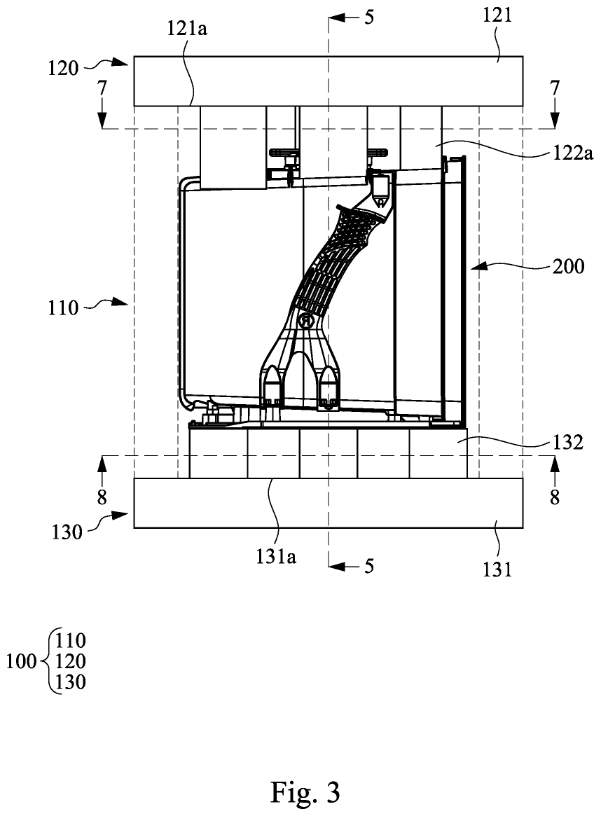

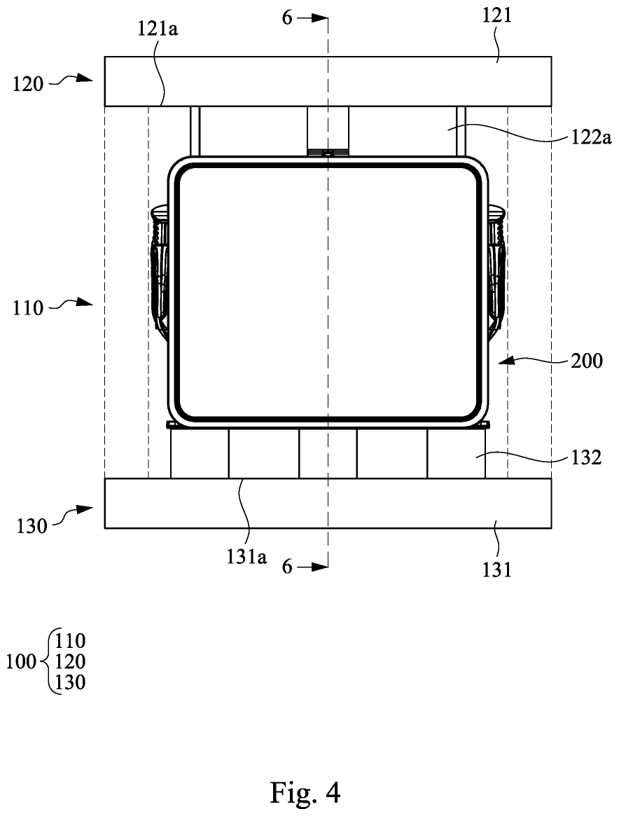

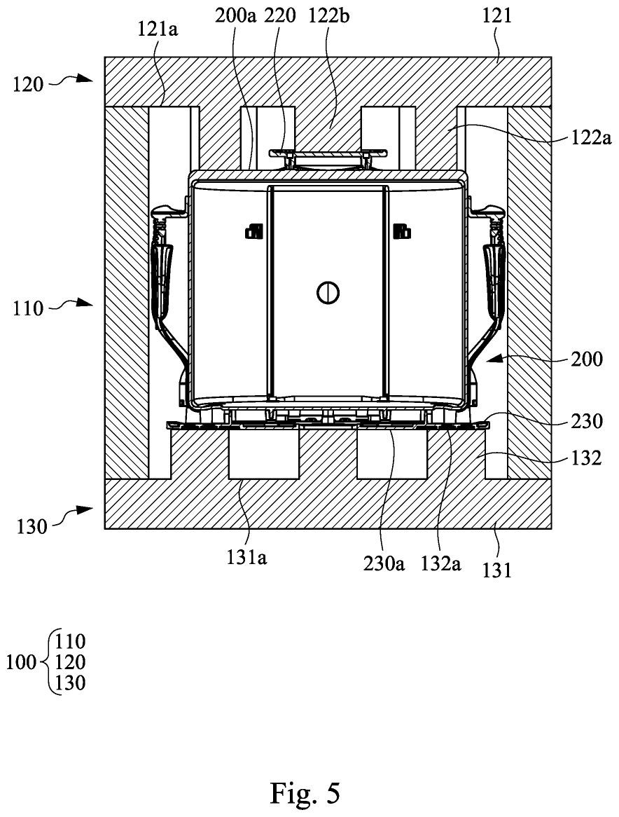

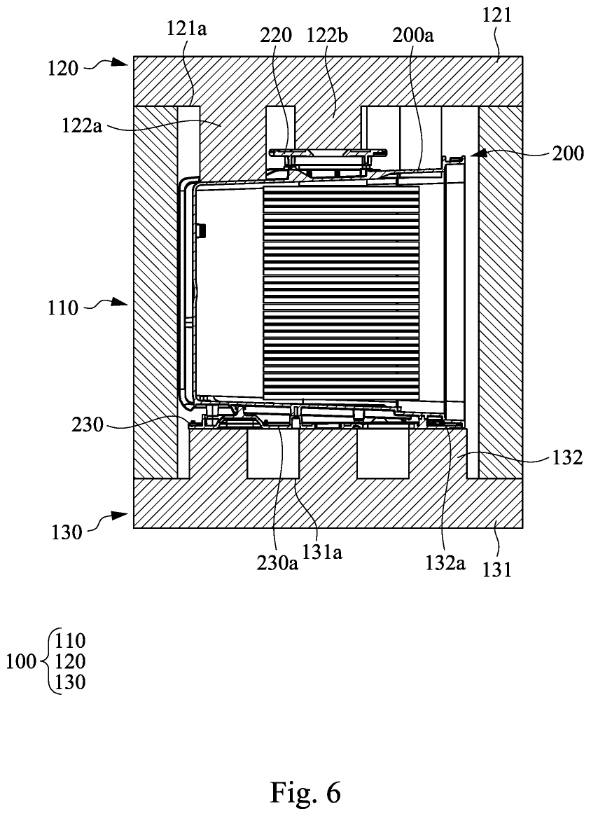

Reference is made to FIGS. 3, 4, 5, and 6. FIG. 3 is a side view of the protective package assembly 100 in FIG. 2 packaging the substrate container 200. FIG. 4 is a front view of the protective package assembly 100 in FIG. 2 packaging the substrate container 200. FIG. 5 is a cross-sectional view of the structure in FIG. 3 cut along line 5-5. FIG. 6 is a cross-sectional view of the structure in FIG. 4 cut along line 6-6. As shown in FIGS. 3 to 6, in the present embodiment, the upper package 120 further includes a plurality of upper buffer members 122a, 122b. The upper buffer members 122a, 122b are distributed at intervals and protrude from a surface 121a of the upper buffer board 121. The upper buffer members 122a, 122b are disposed toward an interior of the accommodating space S. The lower package 130 further includes a plurality of lower buffer members 132. The lower buffer members 132 are distributed at intervals and protrude from a surface 131a of the lower buffer board 131. The lower buffer members 132 are disposed toward the interior of the accommodating space S. By abutting against the upper surface 200a of the substrate container 200 by the upper buffer members 122a, 122b distributed at intervals, the gaps among the upper buffer members 122a, 122b can serve as lateral deformation spaces when squeezed by the substrate container 200 (for example, when the protective package assembly 100 is bumped, pressed, or dropped). Likewise, by abutting against the bottom of the substrate container 200 by the lower buffer members 132 distributed at intervals, the gaps among the lower buffer members 132 can serve as lateral deformation spaces when squeezed by the substrate container 200. Therefore, the cushioning forces of the upper package 120 and the lower package 130 in the present embodiment will be greater than those of a traditional structural design of integrally attached to the substrate container 200, so that the buffering and shockproof effect can be achieved more effectively. In this way, the disadvantage of the prior art that the monolithic structure design does not provide space for lateral deformation and cannot effectively prevent shocks and protection can be solved.

As shown in FIG. 2, the upper surface 200a of the substrate container 200 is provided with a rib portion 210 and a gripping portion 220. The gripping portion 220 is located at the center of the upper surface 200a, and the rib portion 210 surrounds the gripping portion 220. It can be seen that the top structure of the substrate container 200 has an irregular undulating profile. In practical applications, the gripping portion 220 of the substrate container 200 can be lifted or lowered by an overhead lifting transfer system (not shown), so as to transfer and place the substrate container 200 at a predetermined position.

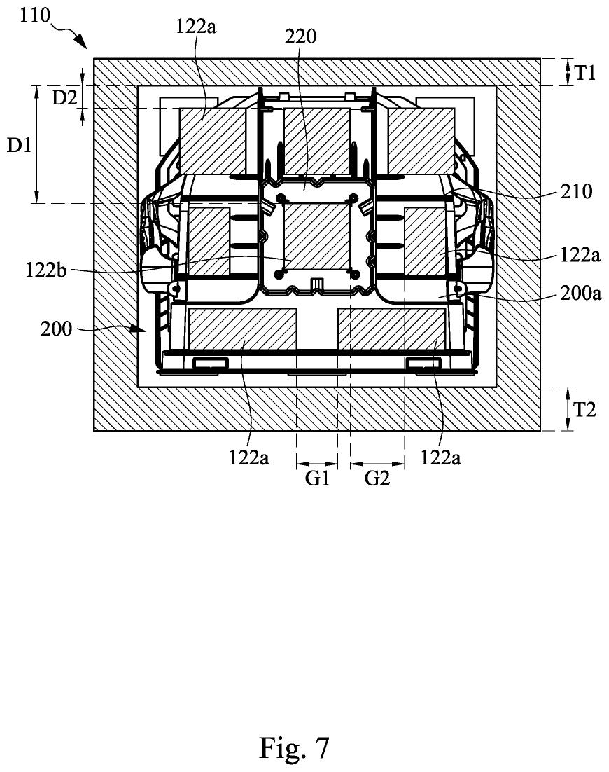

Reference is made to FIG. 7. FIG. 7 is a cross-sectional view of the structure in FIG. 3 cut along line 7-7. As shown in FIGS. 5 to 7, in the present embodiment, the rib portion 210 of the substrate container 200 divides the upper surface 200a into a plurality of regions. The gripping portion 220 of the substrate container 200 is located in one of the regions divided by the rib portion 210, such as the central region. As mentioned above, since the upper buffer members 122a, 122b are distributed at intervals, the gaps among the upper buffer members 122a, 122b can serve as spaces for avoiding the rib portion 210. In addition, the upper buffer members 122a, 122b have different heights relative to the surface 121a of the upper buffer board 121 facing the middle package 110. In the present embodiment, the heights of the upper buffer members 122a protruding from the surface 121a are greater than the height of the upper buffer member 122b. In detail, the upper buffer members 122a with larger heights are configured to abut against the upper surface 200a of the substrate container 200 while avoiding the rib portion 210. The upper buffer member 122b having a smaller height is configured to abut against the gripping portion 220 of the substrate container 200. As shown in FIG. 7, since the gripping portion 220 is located in the central region of the upper surface 200a, the periphery of the upper buffer member 122b abutting against the gripping portion 220 is surrounded by the other upper buffer members 122a.

Specifically, in FIG. 7, the rib portion 210 of the substrate container 200 divides the upper surface 200a into seven regions including an upper left region, an upper middle region, an upper right region, a middle left region, the central region, a middle right region, and a lower region. Since the upper left region, the upper middle region, the upper right region, the middle left region, and the middle right region of the upper surface 200a are relatively similar in area, they can be abutted by five of the upper buffer members 122a respectively. The area of the lower region of the upper surface 200a is obviously larger than other regions and its shape is approximately rectangular, so the lower region can be abutted by two of the upper buffer members 122a. Therefore, a total of seven upper buffer members 122a surround the periphery of the upper buffer member 122b arranged in the center.

As shown in FIG. 7, in the present embodiment, the upper buffer members 122a, 122b are a combination of different areas and arranged at intervals. In addition, there are a plurality of different distances among the upper buffer members 122a, 122b. For example, there is a gap G1 between the two upper buffer members 122a of the upper surface 200a which abut against the lower region, there is a gap G2 between the upper buffer member 122a abutting against the right middle region of the upper surface 200a and the upper buffer member 122b abutting against the central region of the upper surface 200a, and the gap G2 is larger than the gap G1. The gaps among the upper buffer members 122a, 122b are not limited to the gap G1, G2 and can be flexibly adjusted according to the position of the rib portion 210. In this way, the upper package 120 can achieve the maximum surface attaching area to the top structure of the substrate container 200 through the upper buffer members 122a, 122b.

In addition, since the upper buffer member 122b abuts against the central region of the upper surface 200a, the shortest distance D1 from the upper buffer member 122b to the annular inner surface 110c will be greater than the shortest distance D2 from the other upper buffer member 122a to the annular inner surface 110c. For example, as shown in FIG. 7, the shortest distance D2 of the upper buffer member 122a abutting against the upper middle region of the upper surface 200a is smaller than the shortest distance D1.

In practical applications, the actual number and arrangement of the upper buffer members 122a, 122b are designed to match the structure of the upper surface 200a of the substrate container 200. In addition, the above-mentioned division of the upper surface 200a into seven regions is only a preferred embodiment, but it is not limited to this structural design and can be adjusted according to actual applications.

In some embodiments, as shown in FIG. 7, profiles of cross sections of the upper buffer members 122a, 122b are rectangular (including square and rectangular), but the present disclosure is not limited thereto. For example, reference is made to FIG. 5 and FIG. 7 at the same time, the aforementioned cross sections are parallel to the surface 121a of the upper buffer board 121 facing the middle package 110.

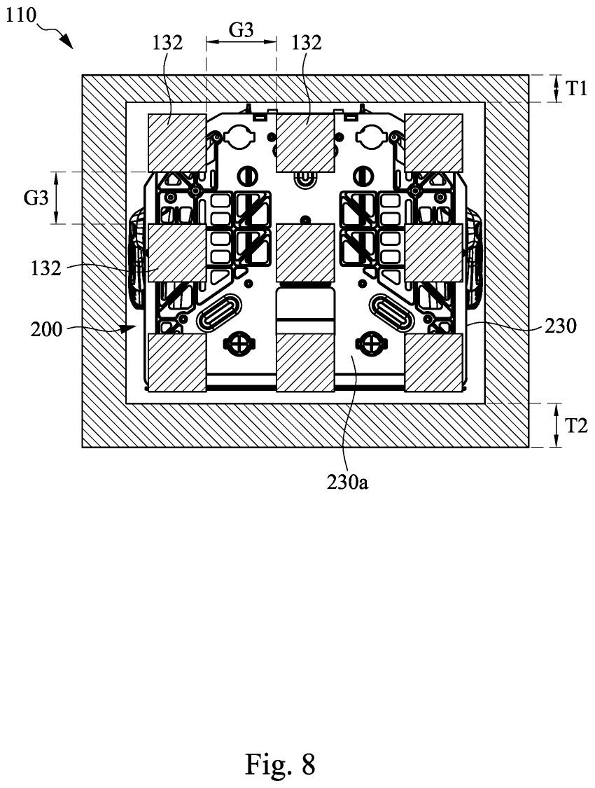

Reference is made to FIG. 8. FIG. 8 is a cross-sectional view of the structure in FIG. 3 cut along line 8-8. As shown in FIGS. 5, 6, and 8, in the present embodiment, the substrate container 200 further includes a bottom plate 230. The lower surface 230a is equivalent to a surface having an irregular undulating contour formed by a plane concaved. The lower buffer members 132 of the lower package 130 has the same height relative to the surface 131a of the lower buffer board 131 facing the middle package 110. In order to abut against the lower surface 230a of the bottom plate 230 more stably, the top surfaces 132a of the lower buffer members 132 (see also FIG. 2) can be coplanar so as to fit more parts of the lower surface 230a of the bottom plate 230.

In some embodiments, the lower buffer members 132 are a combination of an identical area. In addition, the lower buffer members 132 have the same gap. For example, as shown in FIG. 8, there is a gap G3 between any adjacent two of the lower buffer members 132, but the present disclosure is not limited thereto.

In some embodiments, the number of the lower buffer members 132 is nine, but the present disclosure is not limited thereto. In practical applications, the actual number of the lower buffer members 132 can be flexibly modified, and is not limited to the number of the embodiment shown in FIG. 8.

In some embodiments, the lower buffer members 132 are arranged in a matrix. For example, as shown in FIG. 8, the two dimensions forming the aforementioned matrix are perpendicular to each other, but the present disclosure is not limited thereto.

In some embodiments, as shown in FIG. 8, the profiles of the cross sections of the lower buffer members 132 are rectangular (for example, square), but the present disclosure is not limited thereto. For example, reference is made to FIG. 5 and FIG. 8 together, the aforementioned cross sections are parallel to the surface 131a of the lower buffer board 131 facing the middle package 110.

In some embodiments, at least one of the side buffer boards 111 has a thickness smaller than a thickness of other side buffer boards 111. For example, as shown in FIG. 7 and FIG. 8, the thickness T1 of the upper side buffer board 111 is smaller than the thickness T2 of the side buffer boards 111 on the adjacent and opposite sides. In this way, compared with other side buffer boards 111, the upper side buffer board 111 has the smaller thickness T1 so as to increase the distance from the substrate container 200, thereby achieving the effect of increasing the buffer space.

In some embodiments, the middle package 110 is a unitary structure, and the material of the unitary structure includes foam.

In some embodiments, the upper package 120 is a unitary structure, and the material of the unitary structure includes foam.

In some embodiments, the lower package 130 is a unitary structure, and the material of the unitary structure includes foam.

In some embodiments, the aforementioned foam is antistatic foam, such as foamed polyethylene, but the disclosure is not limited thereto. Foamed polyethylene is a lightweight, soft, resilient material with good cushioning properties. It is usually processed, foamed, and molded from polyethylene (PE) resin. The main features of foamed polyethylene are light weight, softness, durability, water resistance, and easy molding.

The applicant provides the actual test results below for reference. The tests are performed in accordance with ISTA 2A (drop) specifications. ISTA 2A is an international shipping packaging testing standard designed to evaluate the drop impact that packages may suffer during transportation. The standard requires packages to be dropped in three directions during the test: faces, edges, and corners. The test height must meet the requirements. If the package is damaged in the drop test, the package fails the test standard. If the package is not damaged in the drop test, the package meets the test standard. Passing the ISTA 2A drop test can ensure that the product will not be affected by the drop impact during transportation, thereby improving the transportation safety and reliability of the product.

Table 1 below shows the drop conditions according to the ISTA 2A (drop) specification.

TABLE 1
Drop conditions

| Object weight | Less than | Free fall |
|---|---|---|
| Kg | Kg | mm |
| 0 | 10 | >970 |

For example, when the protective package assembly 100 of the present disclosure accommodates an object weighing less than ten kilograms and is subjected to a drop test from a height greater than ten centimeters, a total cushioning force of the protective package assembly 100 is greater than cushioning forces of a corner, an edge, and a surface of the protective package assembly 100, and the cushioning forces of the corner and the edge is greater than the cushioning force of the surface. It should be noted that since the protective package assembly 100 of the present disclosure is a combined structure of the middle package 110, the upper package 120, and the lower package 130, no matter where the protective package assembly 100 collides during the drop test, all parts will affect each other and jointly contribute to the total buffering force. Moreover, since the regions of the corner and the edge of the protective package assembly 100 are smaller than the region of the surface, the cushioning forces of the corner and the edge are greater than the cushioning force of the surface.

Table 2 below shows the test results obtained from the drop test after wrapping the object with the protective package assembly 100 of the present disclosure. The object to be wrapped is, for example, a FOUP. The tested protective package assembly 100 is a cube with different sizes in length, width, and height.

TABLE 2

| | | Falling corners, | |
|---|---|---|---|
| Order | Falling part | edges, faces | Test result |
| 1 | Corner | Most vulnerable | Pass |
| | | corner of 3 sides, | |
| | | or test corner | |
| | | 2-3-5 | |
| 2 | Edge | Shortest edge of | Pass |
| | | drop corner | |
| 3 | Edge | Second shortest | Pass |
| | | edge of drop | |
| | | corner | |
| 4 | Edge | Longest edge of | Pass |
| | | drop corner | |
| 5 | Surface | Any smallest | Pass |
| | | surface | |
| 6 | Surface | Another smallest | Pass |
| | | surface | |
| 7 | Surface | Any second | Pass |
| | | smallest surface | |
| 8 | Surface | Another second | Pass |
| | | smallest surface | |
| 9 | Surface | Any largest | Pass |
| | | surface | |
| 10 | Surface | Another largest | Pass |
| | | surface | |

According to the test results shown in Table 2 above, it can be clearly seen that the protective package assembly 100 of the present disclosure can indeed provide sufficient cushioning to protect the substrate container 200.

According to the foregoing recitations of the embodiments of the disclosure, it can be seen that in the protective package assembly of the present disclosure, by virtue of the combined structure of the middle package, the upper package, and the lower package, the outer periphery of the substrate container can be completely covered. Specifically, a plurality of upper buffer members are disposed on the upper buffer board of the upper package, and a plurality of lower buffer members are disposed on the lower buffer board of the lower package. The heights of these upper buffer members and the lower buffer members can be correspondingly adjusted according to the top structure and the bottom structure of the substrate container, so that the upper package and the lower package can closely fit the irregular undulating contours of the top and bottom of the substrate container. Moreover, the cushioning forces of the upper package and the lower package disclosed in the present disclosure are greater than those of a traditional structural design of integrally attached to the substrate container, so the effect of cushioning and shock resistance can be more effectively achieved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A protective package assembly, comprising:
a middle package comprising a plurality of side buffer boards, the side buffer boards being connected in a ring shape to form an accommodating space communicated with an upper opening and a lower opening;
an upper package comprising:
an upper buffer board configured to cover the upper opening; and
a plurality of upper buffer members distributed at intervals and protruding from a surface of the upper buffer board, the upper buffer members being disposed toward an interior of the accommodating space; and
a lower package comprising:
a lower buffer board configured to cover the lower opening; and
a plurality of lower buffer members distributed at intervals and protruding from a surface of the lower buffer board, the lower buffer members being disposed toward the interior of the accommodating space.

2. The protective package assembly of claim 1, wherein the accommodating space of the middle package has an annular inner surface, the upper buffer members comprise a first upper buffer member and a second upper buffer member, a height of the first upper buffer member is greater than a height of the second upper buffer member, and a shortest distance from the second upper buffer member to the annular inner surface is greater than a shortest distance from the first upper buffer member to the annular inner surface.

3. The protective package assembly of claim 1, wherein the upper buffer members comprise a plurality of first upper buffer members and a second upper buffer member, a height of the first upper buffer members is greater than a height of the second upper buffer member, and the first upper buffer members are arranged around a periphery of the second upper buffer member.

4. The protective package assembly of claim 1, wherein top surfaces of the lower buffer members are coplanar.

5. The protective package assembly of claim 1, wherein the upper buffer members are a combination of different areas and arranged at intervals.

6. The protective package assembly of claim 1, wherein the lower buffer members are a combination of an identical area.

7. The protective package assembly of claim 1, wherein when the protective package assembly accommodates an object weighing less than ten kilograms and is subjected to a drop test from a height greater than ten centimeters, a total cushioning force of the protective package assembly is greater than cushioning forces of a corner, an edge, and a surface of the protective package assembly, and the cushioning forces of the corner and the edge is greater than the cushioning force of the surface.

8. The protective package assembly of claim 1, wherein the protective package assembly is a combined structure of the middle package, the upper package, and the lower package.

9. The protective package assembly of claim 1, wherein a material of the middle package, the upper package, and the lower package is foamed polyethylene.

10. The protective package assembly of claim 1, wherein at least one of the side buffer boards has a thickness smaller than a thickness of other side buffer boards.
